(19) United States
(12) Patent Application Publication
(10) Pub. No.: US 2022/0005898 A1
(43) Pub. Date: Jan. 6, 2022

(54) OLED DISPLAY DEVICE AND MANUFACTURING METHOD THEREOF

(71) Applicant: WUHAN CHINA STAR OPTOELECTRONICS SEMICONDUCTOR DISPLAY TECHNOLOGY CO., LTD., Wuhan (CN)

(72) Inventor: Jie LIU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/469,651

(22) PCT Filed: Mar. 19, 2019
(86) PCT No.: PCT/CN2019/078716

§ 371 Date: Jun. 14, 2019

(30) Foreign Application Priority Data
Dec. 13, 2018 (CN) 201811528739.4

(51) Int. Cl. H01L 27/32; H01L 51/52; H01L 51/56

(52) U.S. Cl. CPC H01L 27/3258; H01L 2227/323; H01L 51/56; H01L 51/5237

(57) ABSTRACT

An organic light emitting diode (OLED) display device and a manufacturing method thereof are provided. The OLED display device includes a display component board, a switching thin film transistor, a light emitting layer, and a driving thin film transistor that are disposed on the display component board, wherein the switching thin film transistor includes a first source/drain metal layer and a first active layer with an oxide semiconductor material. The driving thin film transistor includes a second source/drain metal layer and a second active layer with a low temperature polysilicon material, and the second source/drain metal layer is located above an anode metal layer.

### FIELD OF INVENTION

The present disclosure relates to a display technology field, and in particular, to an organic light emitting diode (OLED) display device and a manufacturing method thereof.

### BACKGROUND OF INVENTION

Low temperature polysilicon (LTPS) thin film transistors (TFTs) have advantages of high electron mobility and lower power consumption. The high electron mobility allows a driver circuit to be integrated on a glass substrate, reducing a driver IC, achieving a narrow bezel, and reducing the cost. Therefore, it is used more and more in high-resolution displays.

However, as the resolution becomes higher and higher, currents required for display gradually decrease, resulting in an increase in an area of a non-display area. TFTs adopting an oxide semiconductor can reduce the area while achieving high resolution. Therefore, a technique using a combination of LTPS and an oxide semiconductor has been attracting attention.

The existing hybrid TFTs have a problem of large parasitic capacitance. For organic light emitting diodes (OLEDs), since the OLEDs are driven by currents, the parasitic capacitance affects stability of a circuit signal and reduces picture quality.

### SUMMARY OF INVENTION

An object of the present disclosure is to provide an organic light emitting diode (OLED) display device, the OLED display device includes a display component board, a switching thin film transistor, a light emitting layer, and a driving thin film transistor. The display component board includes a substrate and a plurality of layer structures disposed on the substrate. The switching thin film transistor, the light emitting layer, and the driving thin film transistor are disposed on the display component board. The driving thin film transistor is electrically connected to the switching thin film transistor and an anode metal layer of the light emitting layer. The switching thin film transistor includes a first source/drain metal layer and a first active layer with an oxide semiconductor material. The driving thin film transistor includes a second source/drain metal layer and a second active layer with a low temperature polysilicon material, and the second source/drain metal layer is located above the anode metal layer. A first hole is formed through the layer structures between the second source/drain metal layer and the anode metal layer, and the second source/drain metal layer is electrically connected to the anode metal layer through the first hole.

Furthermore, the OLED display device includes a buffer layer disposed on the substrate, a first insulating layer disposed on the buffer layer, a gate insulating layer disposed on the first insulating layer, a third insulating layer disposed above the gate insulating layer, and a flat layer and an encapsulation layer disposed on the third insulating layer. The second active layer is disposed on the buffer layer, the second source/drain metal layer is located on the third insulating layer, and the driving thin film transistor further includes a second gate disposed on the first insulating layer.

Furthermore, a second insulating layer is further disposed between the gate insulating layer and the third insulating layer.

Furthermore, the first active layer and the first source/drain metal layer are located on the gate insulating layer, and the second insulating layer covers the first active layer and the first source/drain metal layer. The switching thin film transistor further includes a first gate disposed on the first insulating layer, and the first gate and the second gate are independent of each other.

Furthermore, the first gate is a bottom gate, and the second gate is a top gate.

Furthermore, each of the first insulating layer, the second insulating layer, and the third insulating layer is a single-layer structure or a multilayer structure of silicon nitride material or silicon oxide material.

The present disclosure further provide a manufacturing method of the OLED display device, the manufacturing method includes steps of: S10, forming a second active layer with a low temperature polysilicon material on a substrate; S20, forming a first insulating layer covering the second active layer on the substrate; S30, forming a first gate and a second gate on the first insulating layer, wherein the first gate and the second gate are independent of each other; S40, forming a gate insulating layer covering the first gate and the second gate on the first insulating layer; S50, forming a first active layer on the gate insulating layer and a first source/drain metal layer electrically connected to the first active layer; S60, forming a third insulating layer and an anode metal layer above the gate insulating layer; S70, forming a second source/drain metal layer electrically connected to the first source/drain metal layer and the anode metal layer on the third insulating layer, wherein the second source/drain metal layer is electrically connected to the second active layer; and S80, forming a flat layer, a light emitting layer, and an encapsulation layer on the third insulating layer.

Furthermore, in the step S30, the first gate and the second gate are made by one process.

Furthermore, after the step S50 and before the step S60, the manufacturing method further includes step of S90, forming a second insulating layer covering the first active layer and the first source/drain metal layer on the gate insulating layer.

Furthermore, each of the first insulating layer, the second insulating layer, and the third insulating layer is a single-layer structure or a multilayer structure of silicon nitride material or silicon oxide material.

A plurality of insulating layer structures between the second source/drain metal layer 32 and the second active layer 31 are added. The distance between the second source/drain metal layer 32 and the second active layer 31 is increased, the parasitic capacitance is reduced, the picture quality of the display device is improved, and the pixel defining layer is not required, thereby reducing the process flow and reducing the production cost.

### DESCRIPTION OF DRAWINGS

In order to more clearly illustrate the embodiments or prior art technical solutions embodiment of the present disclosure, will implement the following figures for the cases described in prior art or require the use of a simple introduction. Obviously, the following description of the drawings are only some of those of ordinary skill in terms of creative effort without precondition, you can also obtain other drawings based on these drawings embodiments of the present disclosure.

FIG. 1 is a schematic view of an organic light emitting diode (OLED) display device according to an embodiment of the present disclosure.

FIG. 2 is a flow chart of a manufacturing method of the OLED display device according to the embodiment of the present disclosure.

FIGS. 3 to 9 are schematic views of the manufacturing method of the OLED display device according to the embodiment of the present disclosure.

Reference numerals: 10, display component board; 11, substrate; 12, buffer layer; 13, first insulating layer; 14, a gate insulating layer; 15, a second insulating layer; 16, a third insulating layer; 17, a flat layer; 18, an encapsulation layer; 21, a first active layer; 22, a first source/drain metal layer; 221, a first source; 222, a first drain; 23, a first gate; 31, a second active layer; 32, a second source/drain metal layer; 321, a second source; 322, a second drain; 33, a second gate; 40, a light emitting layer; 41, an anode metal layer; 51, a first hole; 52, a second hole; 53, a third hole; 54, pixel opening.

### DETAILED DESCRIPTION OF PREFERRED EMBODIMENTS

Structure and technical means adopted by the present disclosure to achieve the above and other objects can be best understood by referring to the following detailed description of the preferred embodiments and the accompanying drawings. Furthermore, directional terms described by the present disclosure, such as upper, lower, front, back, left, right, inner, outer, side, longitudinal/vertical, transverse/horizontal, etc., are only directions by referring to the accompanying drawings, and thus the used directional terms are used to describe and understand the present disclosure, but the present disclosure is not limited thereto.

The existing hybrid thin film transistor has a problem of large parasitic capacitance, and the existence of parasitic capacitance affects stability of a circuit signal of an organic light emitting diode (OLED) display device, and picture quality is degraded. The present disclosure can solve the above problems.

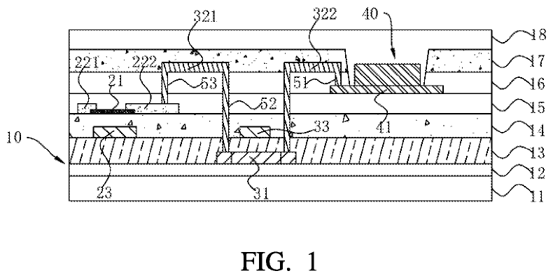

Referring to FIG. 1, an OLED display device includes a display component board 10, a switching thin film transistor disposed on the display component board 10, a light emitting layer 40, and a driving thin film transistor. The driving thin film transistor is electrically connected the switching thin film transistor and an anode metal layer 41 of the light emitting layer 40.

The display component board 10 includes a substrate 11 and a plurality of layer structures disposed on the substrate 11. The switching thin film transistor includes a first source/drain metal layer 22 and a first active layer 21 containing an oxide semiconductor material. The driving thin film transistor includes a second source/drain metal layer 32 and a second active layer 31 containing a low temperature polysilicon material. The second source/drain metal layer 32 is located above the anode metal layer 41. A first hole 51 is formed in a layer structure between the second source/drain metal layer 32 and the anode metal layer 41. A first hole 51 is formed through the layer structures between the second source/drain metal layer 32 and the anode metal layer 41, and the second source/drain metal layer 32 is electrically connected to the anode metal layer 41 through the first hole 51.

By increasing a distance between the second source/drain metal layer 32 and the second active layer 31 in the driving thin film transistor, the parasitic capacitance is reduced, and the stability of the circuit signal is improved. Simultaneously, using a combination of a switching thin film transistor and a driving thin film transistor, the parasitic capacitance is reduced without increasing the thickness of the display device, and a high aperture ratio can be achieved.

Specifically, the display component board 10 includes a buffer layer 12 disposed on the substrate 11, a first insulating layer 13 disposed on the buffer layer 12, and a gate disposed on the first insulating layer 13. A gate insulating layer 14, a third insulating layer 16 disposed over the gate insulating layer 14, and a flat layer 17 and an encapsulation layer 18 disposed on the third insulating layer 16.

The second active layer 31 is disposed on the buffer layer 12, and the second source/drain metal layer 32 is disposed on the third insulating layer 16. The second active layer 31 includes an active island. A second hole 52 is disposed on the layer structures between the second source/drain metal layer 32 and the second active layer 31. The second source/drain metal layer 32 is electrically connected to an ion doping region of the active island through the second hole 52.

Furthermore, a second insulating layer 15 is further disposed between the gate insulating layer 14 and the third insulating layer 16.

By increasing a thickness of the insulating layer between the second source/drain metal layer 32 and the second active layer 31, the distance between the second source/drain metal layer 32 and the second active layer 31 is increased to reduce the parasitic capacitance.

Specifically, the first active layer 21 and the first source/drain metal layer 22 are both located on the gate insulating layer 14, and the second insulating layer 15 covers the first active layer 21 and the first source/drain metal layer 22.

The first source/drain metal layer 22 includes a first source 221 and a first drain 222. The second source/drain metal layer 32 includes a second source 321 and a second drain 322. A third hole 53 extending to a surface of the first drain 222 is disposed between the second source 321 and the first drain 222. The second source 321 and the first drain 222 are electrically connected through the third hole 53. The second drain 322 is electrically connected to the anode metal layer 41 through the first hole 51.

The switching thin film transistor further includes a first gate 23 disposed on the first insulating layer 13. The driving thin film transistor further includes a second gate 33 disposed on the first insulating layer 13. The first gate 23 and the second gate 33 are independent of each other. The first gate 23 and the second gate 33 are made of the same material and formed by the same etching process to reduce the process and save production cost.

The first gate 23 is a bottom gate, and the second gate 33 is a top gate. That is, the first gate 23 of the oxide semiconductor-switched thin film transistor has a bottom gate structure, and the second gate 33 of the low-temperature polysilicon-containing driving thin film transistor has a top gate structure, thereby achieving the purpose of simplifying the process.

It should be noted that, in the display component board 10, the substrate 11 can be a glass or a flexible substrate 11. When the flexible substrate 11 is employed, materials for forming the flexible substrate 11 include, but are not limited to, polyimide (PI) or polyethylene terephthalate (PET).

The buffer layer 12 can be a substrate and a plurality of layer structures of a silicon nitride material or a silicon oxide material.

The first insulating layer 13, the second insulating layer 15, and the third insulating layer 16 are a substrate and a plurality of layer structures of including a silicon nitride material or a silicon oxide material.

The first insulating layer 13, the second insulating layer 15, the third insulating layer 16, and the gate insulating layer 14 are made of the same material. The first hole 51, the second hole 52, and the third hole 53 can be fabricated in the same process by a half mask process, thereby reducing the production process and reducing the cost.

It should be noted that, in the switching thin film transistor, the material of the first active layer 21 is an indium gallium zinc oxide semiconductor (IGZO).

It should be noted that the anode metal layer 41 is made of a transparent conductive metal (ITO) or a composite transparent conductive metal (ITO/Ag/ITO).

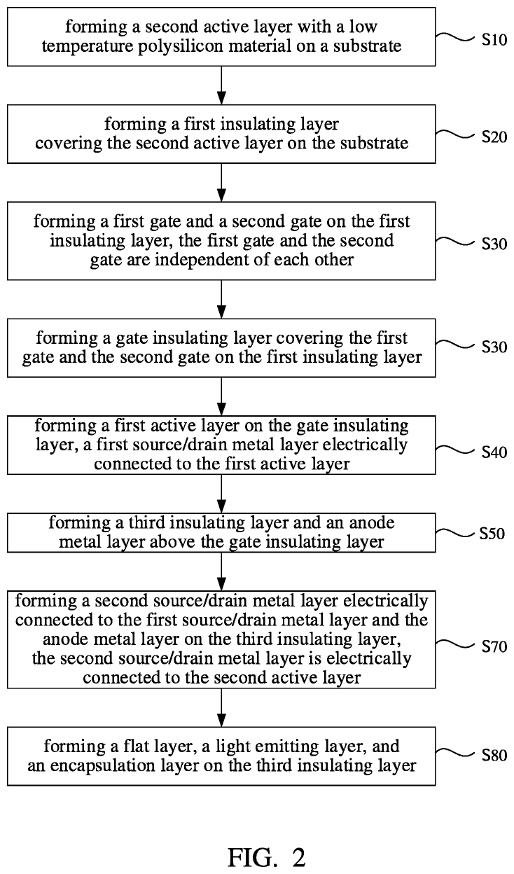

Referring to FIG. 2, based on the above OLED display device, a method for fabricating an OLED display device is also provided. The method includes the following steps:

S10, forming a second active layer 31 with a low temperature polysilicon material on a substrate 11.

S20, forming a first insulating layer 13 covering the second active layer 31 on the substrate 11.

S30, forming a first gate 23 and a second gate 33 on the first insulating layer 13, wherein the first gate 23 and the second gate 33 are independent of each other.

S40, forming a gate insulating layer 14 covering the first gate 23 and the second gate 33 on the first insulating layer.

S50, forming a first active layer 21 on the gate insulating layer 14 and a first source/drain metal layer 22 electrically connected to the first active layer 21.

S60, forming a third insulating layer 16 and an anode metal layer 41 above the gate insulating layer 14.

S70, forming a second source/drain metal layer 32 electrically connected to the first source/drain metal layer 22 and the anode metal layer 41 on the third insulating layer 16, wherein the second source/drain metal layer 32 is electrically connected to the second active layer 31.

S80, forming a flat layer 17, a light emitting layer 40, and an encapsulation layer 18 on the third insulating layer 16.

By increasing the distance between the second source/drain metal layer 32 and the second active layer 31 in the driving thin film transistor, the parasitic capacitance is reduced, and the stability of the circuit signal is improved.

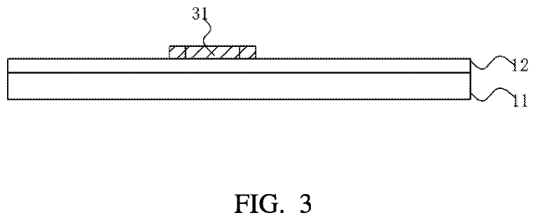

Referring to FIGS. 3 to 9, schematic views of the manufacturing method of the OLED display device according to the embodiment of the present disclosure are illustrated.

Referring to FIG. 3, after the buffer layer 12 is formed on the substrate 11, a second active layer 31 including a low temperature polysilicon material is formed on the buffer layer 12, and the second active layer 31 is patterned.

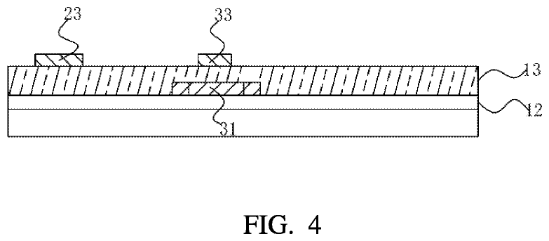

Referring to FIG. 4, after the first insulating layer 13 covering the second active layer 31 is formed on the buffer layer 12, a gate metal layer is formed on the first insulating layer 13, and the gate metal layer is etched to form the first gate 23 and the second gate 33 that are independent of each other.

In the step S30, the first gate 23 and the second gate 33 are formed by the same etching process to reduce the production process.

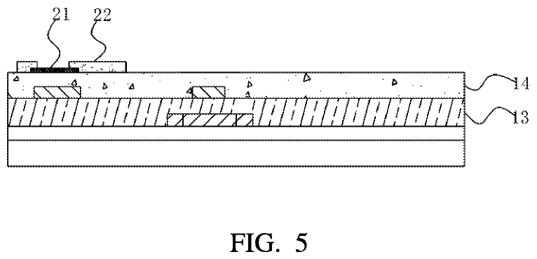

Referring to FIG. 5, after the gate insulating layer 14 covering the first gate 23 and the second gate 33 is formed on the first insulating layer 13, a first active layer 21 and a first source/drain metal layer 22 electrically connected to the first active layer 21 are formed on the gate insulating layer 14.

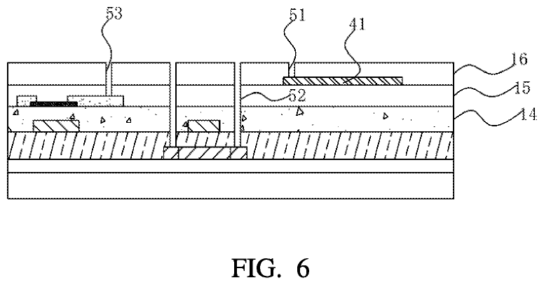

Referring to FIG. 6, a second insulating layer 15 is formed on the gate insulating layer 14, and the second insulating layer 15 covers the first active layer 21 and the first source/drain metal layer 22. An anode metal layer 41 and a third insulating layer 16 covering the anode metal layer 41 are formed on the second insulating layer 15.

The first insulating layer 13, the second insulating layer 15, and the third insulating layer 16 are each a substrate and a plurality of layer structures including a silicon nitride material or a silicon oxide material. The first insulating layer 13, the second insulating layer 15, the third insulating layer 16, and the gate insulating layer 14 are made of the same material.

After the third insulating layer 16 is formed, processing a process on the third insulating layer 16 by a half mask process, a first hole 51 extending to a surface of the anode metal layer 41 is formed, a second hole 52 extending to a surface of the second active layer 31 is formed, and a third hole 53 extending to a surface of the first source/drain metal layer 22 is formed.

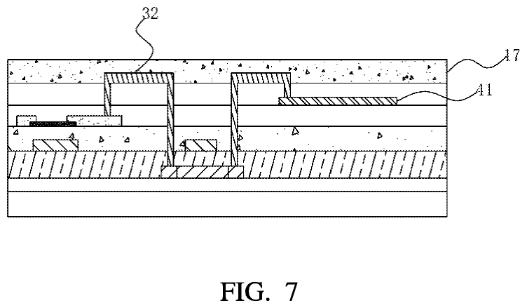

Referring to FIG. 7, a second source/drain metal layer 32 is formed on the third insulating layer 16, and the second source/drain metal layer 32 fills the first via 51, the second via 52, and the third via 53. A flat layer 17 is formed and covers the second source/drain metal layer 32 on the third insulating layer 16.

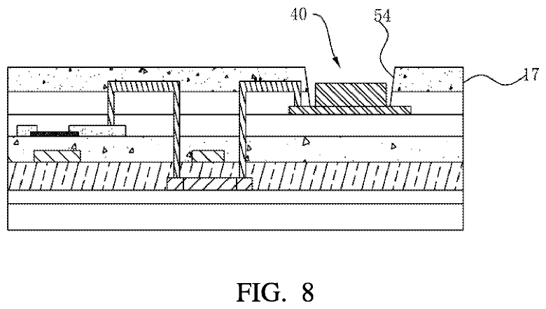

Referring to FIG. 8, a pixel opening 54 is formed on the third insulating layer 16 and the flat layer 17 above the anode metal layer 41, and a light emitting layer 40 is formed in the pixel opening 54.

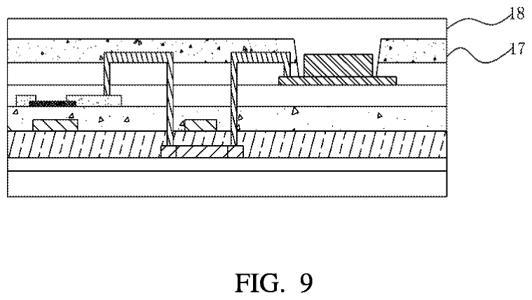

Referring to FIG. 9, an encapsulation layer 18 is formed on the flat layer 17.

The beneficial effects of the present disclosure are that a plurality of insulating layer structures between the second source/drain metal layer 32 and the second active layer 31 are added. The distance between the second source/drain metal layer 32 and the second active layer 31 is increased, the parasitic capacitance is reduced, the picture quality of the display device is improved, and the pixel defining layer is not required, thereby reducing the process flow and reducing the production cost.

The present disclosure has been described with preferred embodiments thereof and it is understood that many changes and modifications to the described embodiments can be carried out without departing from the scope and the spirit of the disclosure that is intended to be limited only by the appended claims.

What is claimed is:

1. An organic light emitting diode (OLED) display device, comprising:
a display component board including a substrate and a plurality of layer structures disposed on the substrate;
a switching thin film transistor, a light emitting layer, and a driving thin film transistor that are disposed on the display component board; the driving thin film transistor being electrically connected to the switching thin film transistor and an anode metal layer of the light emitting layer;
wherein the switching thin film transistor includes a first source/drain metal layer and a first active layer with an oxide semiconductor material;
wherein the driving thin film transistor includes a second source/drain metal layer and a second active layer with a low temperature polysilicon material, and the second source/drain metal layer is located above the anode metal layer;
wherein a first hole is formed through the layer structures between the second source/drain metal layer and the anode metal layer, and the second source/drain metal layer is electrically connected to the anode metal layer through the first hole.

2. The OLED display device according to claim 1, wherein the OLED display device includes a buffer layer disposed on the substrate, a first insulating layer disposed on the buffer layer, a gate insulating layer disposed on the first insulating layer, a third insulating layer disposed above the gate insulating layer, and a flat layer and an encapsulation layer disposed on the third insulating layer;
the second active layer is disposed on the buffer layer, the second source/drain metal layer is located on the third insulating layer, and the driving thin film transistor further includes a second gate disposed on the first insulating layer.

3. The OLED display device according to claim 2, wherein a second insulating layer is further disposed between the gate insulating layer and the third insulating layer.

4. The OLED display device according to claim 3, wherein the first active layer and the first source/drain metal layer are located on the gate insulating layer, and the second insulating layer covers the first active layer and the first source/drain metal layer;
the switching thin film transistor further includes a first gate disposed on the first insulating layer, and the first gate and the second gate are independent of each other.

5. The OLED display device according to claim 4, wherein the first gate is a bottom gate, and the second gate is a top gate.

6. The OLED display device according to claim 3, wherein each of the first insulating layer, the second insulating layer, and the third insulating layer is a single-layer structure or a multilayered structure of a silicon nitride material or a silicon oxide material.

7. A manufacturing method of an organic light emitting diode (OLED) display device, comprising steps of:
S10, forming a second active layer with a low temperature polysilicon material on a substrate;
S20, forming a first insulating layer covering the second active layer on the substrate;
S30, forming a first gate and a second gate on the first insulating layer, wherein the first gate and the second gate are independent of each other;
S40, forming a gate insulating layer covering the first gate and the second gate on the first insulating layer;
S50, forming a first active layer on the gate insulating layer and a first source/drain metal layer electrically connected to the first active layer;
S60, forming a third insulating layer and an anode metal layer above the gate insulating layer;
S70, forming a second source/drain metal layer electrically connected to the first source/drain metal layer and the anode metal layer on the third insulating layer, wherein the second source/drain metal layer is electrically connected to the second active layer; and
S80, forming a flat layer, a light emitting layer, and an encapsulation layer on the third insulating layer.

8. The manufacturing method of the OLED display device according to claim 7, wherein in the step S30, the first gate and the second gate are made by one process.

9. The manufacturing method of the OLED display device according to claim 7, wherein after the step S50 and before the step S60, the manufacturing method further comprises step of:
S90, forming a second insulating layer covering the first active layer and the first source/drain metal layer on the gate insulating layer.

10. The manufacturing method of the OLED display device according to claim 9, wherein each of the first insulating layer, the second insulating layer, and the third insulating layer is a single-layer structure or a multilayer structure of silicon nitride material or silicon oxide material.
